(19) United States
(12) Patent Application Publication
(10) Pub. No.: US 2015/0136205 A1
(43) Pub. Date: May 21, 2015

(54) SOLAR PANEL BALLASTED GROUND SUPPORT SYSTEMS

(71) Applicant: Andrew Barron Worden, New York, NY (US)

(72) Inventor: Andrew Barron Worden, New York, NY (US)

(21) Appl. No.: 14/321,801

(22) Filed: Jul. 1, 2014

Related U.S. Application Data
(60) Provisional application No. 61/906,085, filed on Nov. 19, 2013.

(51) Int. Cl. H01L 31/042; H01L 31/18

(52) U.S. Cl. CPC H01L 31/0422; H01L 31/18
USPC 136/251; 29/890.033

(57) ABSTRACT

A structure, system and method for the in situ ballasting of solar panel ground support structures, the method, system and structures comprising the positioning of supporting posts or anchoring elements therefor within a peripherally enclosing frame, having an open top and preferably open bottom, on the ground at a final solar panel array supporting position. The supporting posts or anchoring elements therefor are vertically aligned and maintained in position relative to each other and a ballast material, such as concrete, is poured into the enclosing frame around the supporting posts or anchoring elements therefor in the final solar panel supporting position thereof with the ballast material being allowed to harden. A solar panel support structure is constructed with the solar panel support structure being ballasted, in final solar panel array position, in situ. Thereafter solar panels are placed on the ballasted support structure to provide the solar panel array.

This application is a non-provisional application of provisional application Ser. No. 61/906,085, filed Nov. 19, 2013, the entire disclosure of which is incorporated herein by reference thereto.

### FIELD OF THE INVENTION

This invention relates to support systems for solar panels and particularly to ground systems with ballasted support provided in situ.

### BACKGROUND

Large-scale solar panel arrays are currently provided with two major types of support systems. A first type is referred to as a roof system, which, as the name implies, embodies relatively light structures which are integrated with rooftops and roofing structures. These structures are limited in size as a function of rooftop areas and roof support capabilities

A second major type of support system is referred to as a “ground system”, which, as opposed to roof systems, can be and often is quite extensive in area (solar panels provide energy as a function of areal sunlight capture and require large areas for viable energy production) and which are accordingly difficult to protect and are highly susceptible to weather conditions. In particular, high or sustained wind conditions may either damage solar panels over time or, more commonly, cause the panels to move out of optimal position for sunlight capture.

Typically, solar panel arrays comprise flat solar panels arranged on supporting structures usually of a fixed grid nature. The supporting structures are configured to hold the panels at an angle relative to the supporting ground such that the solar panels optimally face and capture sunlight for maximum energy conversion.

The structure of a solar panel array includes spaced apart pairs of vertical posts referred to in the art as North and South Posts based on their relative positioning relative to sunlight direction. Other intermediate or otherwise positioned posts such as Center Posts may be and are often utilized in various support structures with North and South Posts being the most common. Reference to North and South Posts herein is used in a non-limiting sense as generally exemplifying support posts. With a specific relative comparison of North and South Posts, the North Post is relatively longer than the South Post such that lateral connections between respective adjacently laterally positioned North Posts and adjacently laterally positioned South Posts provide an angular plane support for the solar panel arrays (generally only for ballasted ground systems as described hereinafter)

Because of the extensive area occupied by viable energy producing solar panels and the large number of panels typically used, efficiencies of scale and proper deployment present numerous problems. In addition, because of the exposed nature of the solar panels, ambient environmental conditions play a large factor in determination of supporting structure configurations, which can maintain proper positioning and support of the panels.

One current system of maintaining solar panel array integrity and positioning in a ground system is that of the ballasted system wherein the base of the solar panel array support structure, e.g., pairs of North and South Posts are provided with or are encased in very heavy and substantially environmentally immovable ballasting materials such as concrete blocks on supporting pans or enveloping concrete.

Alternatively, instead of directly encasing the supporting posts within the ballasting material, a supporting member such as an elongated bolt is imbedded within the enveloping concrete with an upper engaging portion remaining exposed for the supporting connection to the posts via bolt-connected plates and the like. The bolts and the like accordingly function as concrete imbedded anchoring extensions of the posts.

In the enveloping concrete system the post elements of the support structure (or anchoring extensions thereof) are encased in ballasting concrete at a production site and then transported to the array site for final assembly of the support structure and deployment or emplacement of the solar panels on the support structure. It is understood that reference herein after to the imbedding of the support posts within concrete or similar materials includes the imbedding of support post anchoring elements such as elongated bolts with connecting plates and the like. Numerous pre-fabricated reusable forms are used to encasingly pre-cast support structure elements with ballasting concrete. After the concrete has dried, the separate encased support structure elements are removed from the reusable forms and are transported to the site for the solar panel array for component alignment and assembly. Full off-site structure assembly is however nearly impossible because of the weight of concrete encased components and the extremely unwieldy large structure for transport and proper positioning.

The current method of off-site ballasting and transport though effective in providing a final ballasted structure has however proven to still be unwieldy and uneconomical, especially with the extent of ballasting required for large-scale arrays. In addition proper alignment of pre-cast components on uneven ground has proven to be problematic.

### SUMMARY OF THE INVENTION

It is accordingly an object of the present invention to provide a ballasting structure, system and method, which obviates the necessity for uneconomical and unwieldy transport of precast very heavy ballasting materials while providing a viable environmentally-resistant position anchoring of solar panel array supporting structures.

It is a further object of the present invention to provide an economical and effective method for the in situ formation of ballasting support for solar panels and solar panel array supporting structures at the final position placement of the solar array.

Generally the present invention comprises a structure, system and method for the in situ ballasting of solar panel support structures in a ground support system. The method comprises the steps of:
i. positioning at least one peripherally enclosing disposable or one-time use frame or framing element having an open top and open or closed bottom, on the ground, with encircling walls of the at least one frame element being positioned to peripherally enclose a final solar panel supporting position of one or more supporting posts such as the Center Posts or North and South Posts and/or support post anchoring elements; and
ii. placing the one or more supporting posts and/or support post anchoring elements within the at least one frame element and aligning the one or more supporting posts for the solar panel, usually substantially vertical (with up to about a 20 degree maximum deviation from normal, with respect to the ground) or to support solar panel mounting rails aligned with each other within the at least one frame element. In this regard it is immaterial with respect to precedence of placement of either the framing element or the supporting posts, though for logistical reasons it is preferred to first place the framing element and then the posts therewithin for subsequent supporting steps;
iii. once the framing elements and posts are positioned relative to each other, attaching the substantially vertically placed and aligned one or more supporting posts to at least one post support member, preferably within the at least one frame element, with the post support member being configured to maintain the at least one post support such as a Center Post or a pair of North and South Posts of a solar panel support structure into a fixed relative position, usually substantially parallel to each other, on the ground, for support of a solar panel array, at the final solar panel supporting position thereof respectively;
iv. repeating steps i-iii, as required, for a desired number of supporting posts for support of the solar panel array;
v. connecting appropriate supporting posts to provide rigid structural and angled support for the solar panel array to be placed thereon; and
vi. filling the frame elements around the supporting posts either before, or between steps iv and v or after step v, with a ballast material, preferably poured concrete, in the final solar panel supporting position thereof with the ballast material being allowed to harden to provide the ballasted solar panel support structure in situ or alternatively filling the frame elements with a non-hardening ballast material such as gravel or rocks, with which a metal tray is attached to the bottom of the posts to provide support and ballasting of the posts thereby; and
vii. thereafter placing solar panels on the ballasted support structure to provide the solar panel array.

In an embodiment wherein anchoring elements are utilized, as described above, the anchoring elements are positioned and aligned within the frame elements in a manner similar to that of the supporting posts and imbedded within the ballast material such as concrete. Once imbedded, the anchoring elements are used to be integrally and supportingly connected to the support posts for construction of the ballasted support structure.

It is understood that the above steps, such as of paragraphs i and ii are not necessarily sequential with either the frame being placed before placement of the posts therewithin or with the posts being initially placed and frame being thereafter placed therearound. Pouring of the ballasting material is also not necessarily sequential with respect to the formation of the support structure since the rigid final position ballasting of the support posts permits support structure building at any time relative to the ballasting. It is however highly preferred that the supporting structure be fully aligned, especially on uneven ground, while the elements are relatively light and more amenable to adjustment, before the deployment of heavy ballasting materials such as poured concrete.

In a preferred embodiment of the invention, each framing element is comprised of an elongated tub comprised of a disposable and economical plastic such as polystyrene, polypropylene, polyethylene, nylon and the like. If necessary the walls of the framing element may be supportingly buttressed such as with planking to provide the requisite containment of poured ballasting material such as concrete. Even rigid cardboard, wood, Styrofoam, or other materials of sufficient strength to substantially (defined as sufficient to provide an acceptable mold for production of a poured concrete ballast) contain poured ballasting material such as concrete, gravel or other spreadable heavy materials from spreading, may be used to provide the framing element of a tub with an open upper end and a preferably substantially open lower end. Preferably the framing tub particularly of thin plastic material is provided with one or more lower cross bar elements which extend between opposing walls in order to provide additional structural strength in maintaining poured ballasting material from detrimentally spreading. It is highly preferred that the concrete directly contact the ground within the frame or tub to prevent even minimal sliding of the frame or tub out of its initial fixed position and an open bottom tub is accordingly preferred. This provides for prevention of dislocation of the respective supporting posts such as Center Posts or North and South Posts from an ideal placement or position for support structure building. Once the ballasting concrete has hardened or with placement of heavy non-hardening ballast materials, the disposable frame elements and tubs remain in place around the ballasting materials.

Though the present system, particularly with the use of poured concrete, requires the on-site deployment of heavy machinery such as concrete mixers and pourers, not necessary with the pre cast supports of the prior art, the advantages with respect to proper adjustments and overall support structure deployment and construction have been found to far outweigh any disadvantages engendered with the need for on-site heavy concrete pouring materials. In addition, whereas the prior art system requires full concrete drying before removal from the reusable forms, the in situ ballasting formation only requires a structural supportive hardening before a solar panel support structure and array can be completed thereby speeding up the ground system construction for solar panels.

Separate smaller frame elements may be used for each of the supporting posts though it is preferred that one relatively larger frame element be utilized for closely adjacent pairs of support posts. Generally and most advantageously, framing tubs are about six to twelve feet in length with standard support posts being positioned therein at four foot interval to support standard size solar panels and arrays.

The embodiment of poured cement preferably employs one of the following procedures, generally determined by ambient conditions:

With the use of disposable plastic tubs, the walls of the tub may require shoring against the weight of poured concrete. Accordingly, plywood pieces may be utilized to this effect wherein the plywood pieces are provided which are the length of straight walls of tub, one outside each wall of the tub and tub straps are provided evenly along the length of the plywood to hold them in place during the concrete pouring

Concrete should be mixed according to industry standard such as Redi-Mix concrete for high strength and long life (3,000 psi minimum), with a weight of approximately 4,000 pounds per cubic yard. The concrete is preferably poured with a five inch slump.

For narrow row spacing or if concrete pouring is on weight constrained landfill cap where it is not possible to use a Redi-Mix truck for pouring, machinery known as bobcats with pouring buckets may be utilized. Alternatively, elephant trunks or concrete pump trucks may be used:

In situ poured concrete is allowed to set one to two days prior to removing the tub straps (and plywood used to shore up plastic tubs. The concrete is allowed to set to full strength, prior to using mounting modules for the solar panels

The above and other objects, features and advantages of the present invention will become more evident from the following discussion and drawings in which:

### SHORT DESCRIPTION OF THE DRAWINGS

FIGS. 1A and 1B show the framing tub of the present invention, with cross bar post supporting elements;

FIG. 2 is an enlarged view of a framing tub with North and South Posts situated therein and interconnected;

FIGS. 2A-2C depict a typical pair of North and South Posts (with framing tub as removed for visibility) as positioned, supported and interconnected respectively in a stable configuration on a final ground site, prior to being encased in concrete

FIG. 3 is an aligned placement of three framing tubs with aligned posts for interconnection to provide a support structure for solar panels;

FIG. 3A shows the interior of a framing tub with aligning and substantially vertical positioning of the support posts;

FIG. 4 shows the framing tubs of FIG. 3 in which the support posts have been interconnected and the tubs filled with poured concrete to ballast and anchor the support structure;

FIG. 5 shows the gradual placement of solar panels on the ballasted and anchored support structure of FIG. 4;

FIG. 6 depicts the three framing tubs with ballasted supports with eight solar panel array fully arranged thereon;

FIG. 7 depicts shoring up of a thin plastic disposable frame tub prior to pouring of concrete therein; and FIGS. 8A-8C respectively show concrete pouring with a pouring bucket on a bobcat, a standard concrete pump truck with a long range; and the use of a concrete pump.

### DETAILED DESCRIPTION

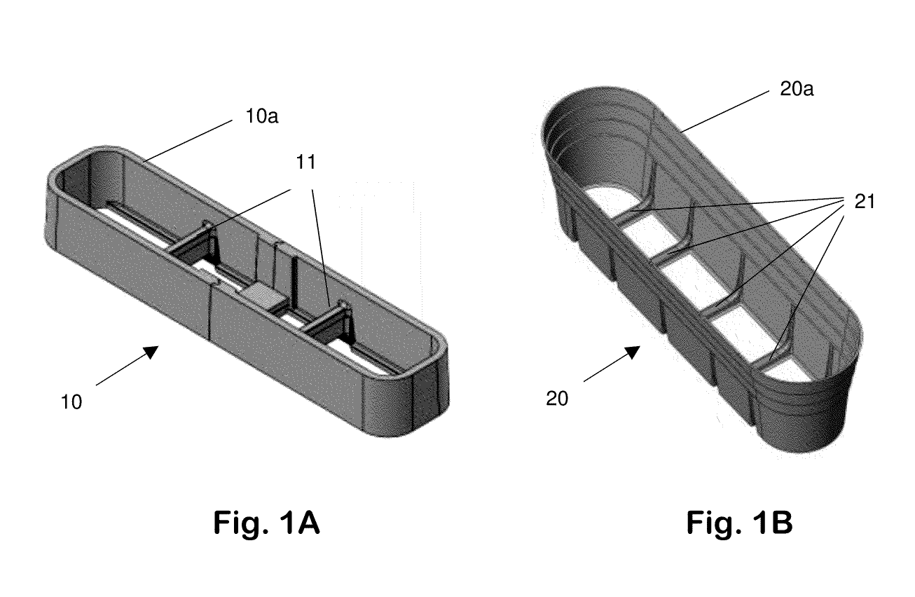

With reference to the drawings, FIGS. 1A and 1B depict two examples 10 and 20 of disposable one time use framing tubs utilizable in the method and system of the present invention. The disposable framing tub 10 is comprised of a structurally supportive Styrofoam material and the framing tub 20 is a plastic material such as polystyrene, polyethylene and the like which may further require temporary shoring of the side while concrete is poured therein. The tubs are configured with continuous side walls 10a and 20a respectively but with open tops and bottoms. Plastic cross rails, bars, or beams 11 and 21 respectively extend interiorally from opposing side walls 10a and 20a and function to provide resistance against the outward spreading of the plastic under poured concrete pressure.

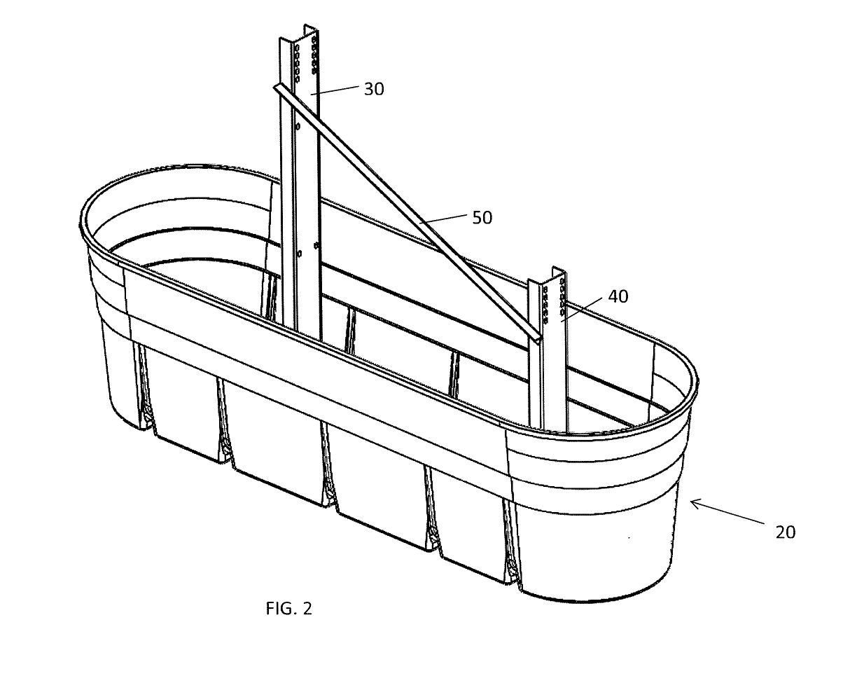

Vertically aligned North Post 30 and South Post 40 are shown in FIG. 2 within framing tub 20, with the posts being angularly attached with bar 50 for subsequent solar panel support. The framing tub 20 and the supporting posts are positioned in a final position for supporting the solar panel array and are not moved thereafter.

As more clearly seen in sequential FIGS. 2A-2C North and South Posts are vertically positioned in parallel to each other at a standard approximate four foot distance from each other in FIG. 2A. In FIG. 2B North Post 30 is shown as being provided with a supporting base 35 and in FIG. 2C the North and South Posts are stably interconnected with angle upper cross bar 50 and lower rail 55 which extends to the ends of the tub 20 shown in FIG. 2.

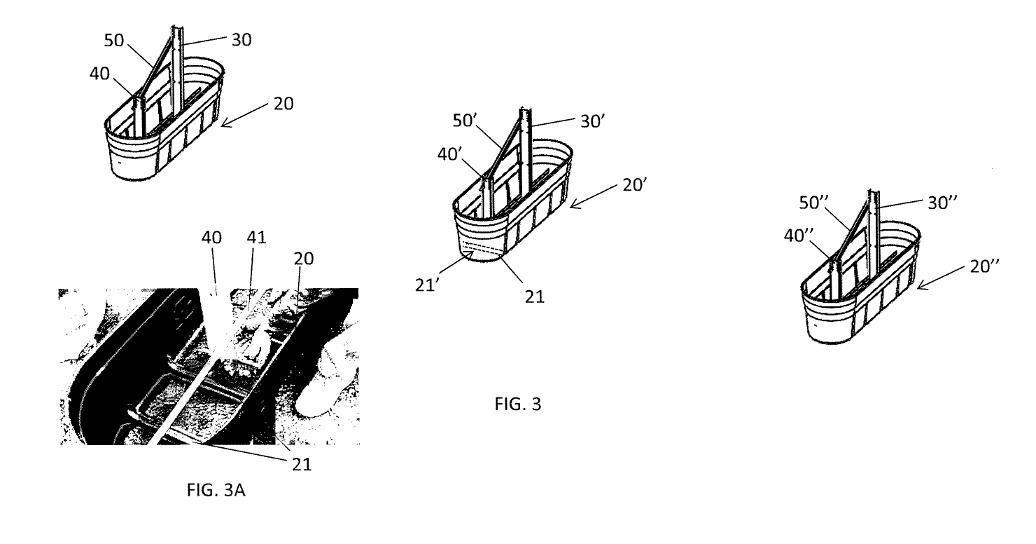

As shown in FIG. 3A the respective posts are vertically adjusted on typically uneven ground prior to the pouring of concrete with self leveling adjustments. This is in addition to a vertical adjustability possible with moving the mounting rail 55 to higher or lower slots (not shown) on the posts. placement of crushed rocks or gravel as shown beneath the respective posts provides further exacting leveling to a desired optimal position.

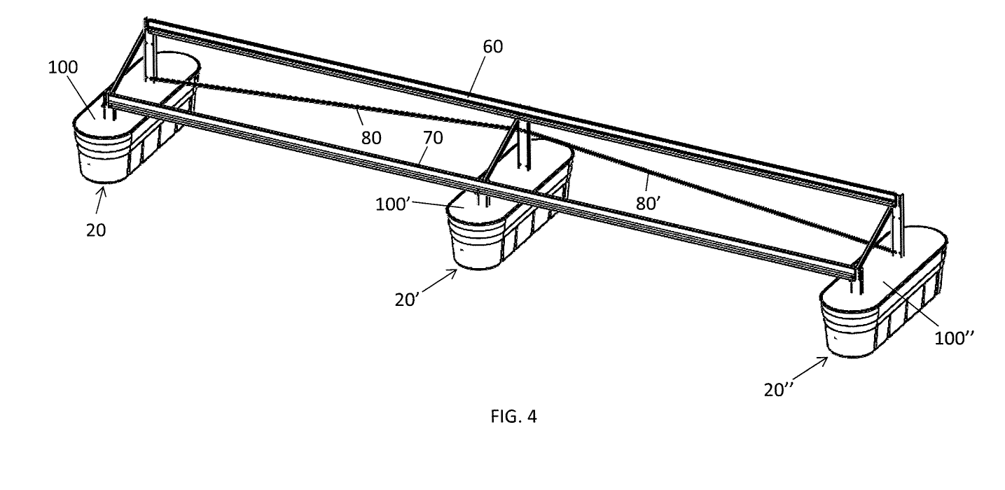

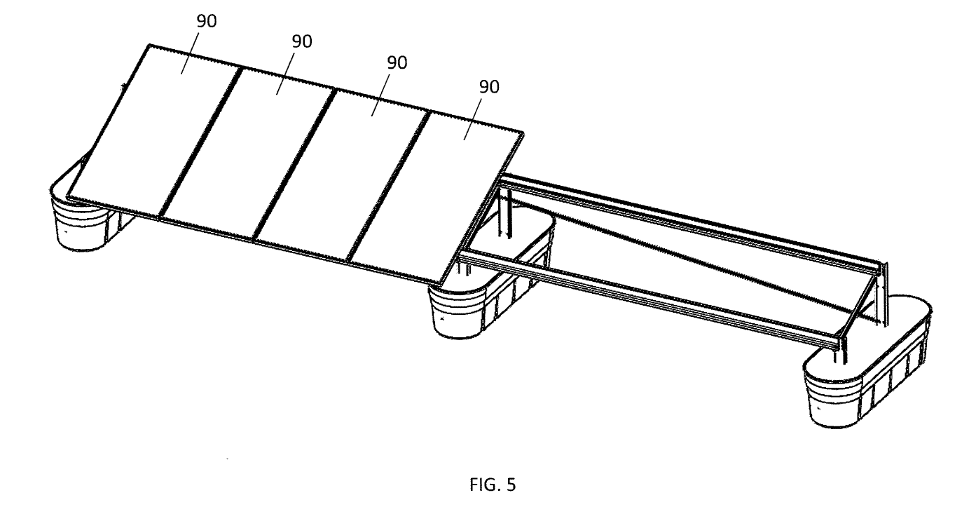

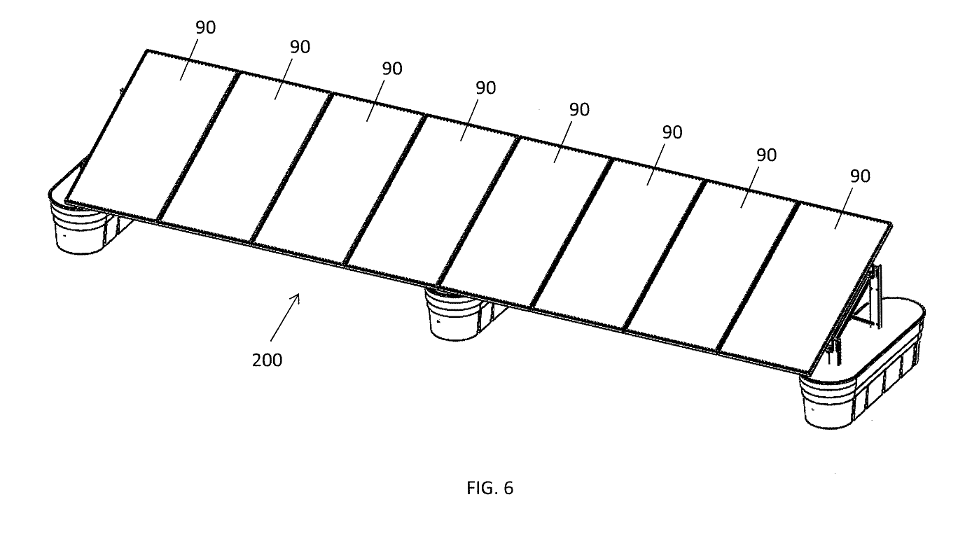

FIG. 3 illustratively depicts three framing tubs 20′ and 20″ spaced apart and in the respective final positions. Each of the framing tubs encloses respective pairs of North and South Posts, 30/40; 30′/40′, and 30″/40″ with respective angled cross connection rods 50, 50′ and 50″. Though not visible, the respective bases of the posts are positioned and anchored within the respective framing tubs to maintain them in aligned vertical position when concrete is poured into each of the framing tubs as shown in FIG. 4. The poured in place concrete provides the in situ formation of ballasting element 100, 100′ and 100″ respectively which solidly anchor the supporting structure against any movement engendered by environmental conditions and the like. Cross connecting beams or bars 60, 70, 80 and 80′ provide the rigidified structure with which the solar panels 90 shown in FIGS. 5 and 6 are supported to form the solar panel array 200. The cross connecting beams or bars 60, 70, 80 and 80′ are placed into position and integrated with the support posts either before or after the concrete is poured in place in each of the framing tubs.

The poured concrete is retained within each of the framing tubs 20, 20′, 20″. . . and for as many support elements as needed. The poured concrete directly contacts the ground and provides a non-slip support. In addition, the concrete surrounds the interior post supporting cross rails of each of the tubs, whereby the framing tubs become essentially non removable.

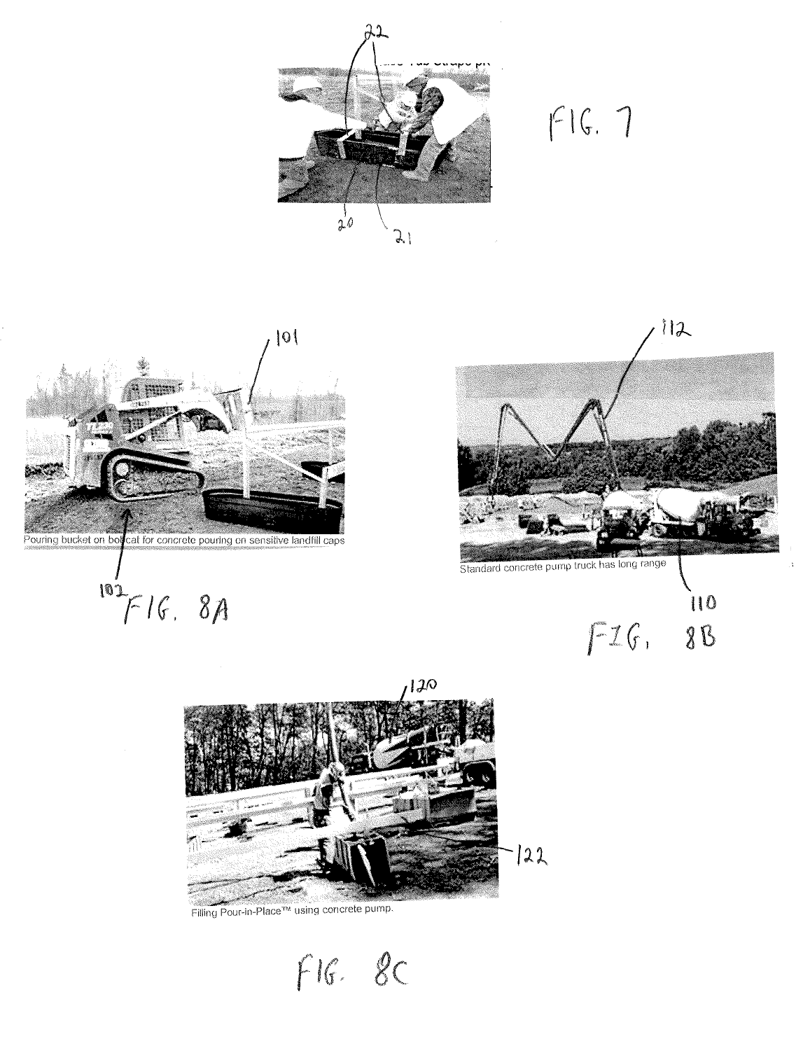

FIG. 7 shows the framing tub 20 being prepared for concrete pouring with plywood side braces 21 and tub straps 22 to hold the braces in place during concrete pouring and setting.

FIGS. 8A-8C show several non-limiting ways of pouring concrete with concrete pouring machinery of a pouring bucket 101 on a bobcat 102, a concrete pump truck 110 with a long range feeder 112, and a concrete pump 120 with sluices 122.

It is understood that above description and drawings are merely illustrative of the present invention and that structures, elements, procedures and materials and the like may vary without departing from the scope of the present invention as defined in the following claims.

1. A method for the in situ ballasting of solar panel array support structures in a ground support system, the method comprises the steps of:
i. positioning at least one peripherally enclosing disposable single use frame element having an open top and an open or closed bottom, on the ground, with encircling walls of the at least one frame element being positioned to peripherally enclose a final solar panel supporting position of one or more supporting posts or anchoring elements therefor;
ii. positioning the one or more supporting posts or anchoring elements therefor within the at least one frame element and substantially vertically aligning the one or more supporting posts or anchoring elements therefor, for the solar panel with each other within the at least one frame element;
iii. providing the supporting posts or anchoring elements therefor with at least one post support member, with the post support member being configured to maintain the at least one post support or anchoring element therefor in a fixed relative position to the ground, for support of a solar panel array, at the final solar panel supporting position thereof respectively;
iv. repeating steps i-iii, as required, for a desired number of supporting posts or anchoring elements therefor for support of the solar panel array;
v. connecting appropriate supporting posts to provide structural support for the solar panel array to be placed thereon; wherein step i may precede or come after steps ii, iii and iiv or may come between steps ii and iii, or between steps iii and iv and
vi. filling the frame elements around the supporting posts or anchoring elements therefor either before or after step v, with a ballast material, in the final solar panel supporting position thereof with, if necessary, the ballast material being allowed to harden to provide the ballasted solar panel support structure in situ;
vii. supportingly integrating any anchoring elements with adjacent supporting posts, and
viii. thereafter placing solar panels on the ballasted support structure to provide the solar panel array.

2. The method of claim 1, wherein the ballasting material comprises a flowable fill material.

3. The method of claim 2 wherein the flowable fill material comprises poured concrete.

4. The method of claim 1, wherein the ballasting fill material is comprised of one or more materials selected from gravel, concrete blocks, concrete pieces, crushed bricks and rocks.

5. The method of claim 3, wherein the frame element is comprised of structurally supported plastic with a strength and rigidity sufficient to substantially maintain poured concrete from spreading therewithin, for concrete setting.

6. The method of claim 1, wherein the solar panel support structure is adjusted and constructed on an even or uneven ground prior to filling the frame elements with the ballast material

7. The disposable single use frame element of claim 5, wherein opposing lateral walls of the lateral wall structure are integrally connected with rail elements configured to provide position maintaining support for solar panel supporting posts placed within the frame element.

8. A frame element for use in the method of claim 1 comprising an encircling lateral wall structure configured to maintain poured concrete therein in place with an open top sufficient to permit pouring of concrete or placement of gravel or rocks therewithin and with an open bottom to permit the poured concrete to contact and rest on ground on which the frame element is placed.
